(19) United States
(12) Patent Application Publication
(10) Pub. No.: US 2026/0259488 A1
(43) Pub. Date: Sep. 3, 2026

(54) MASK PATTERN OPTIMIZATION METHOD, ELECTRONIC DEVICE, AND PROGRAM PRODUCT

(71) Applicant: SHENZHEN JINGYUAN INFORMATION TECHNOLOGY CO., LTD, Shenzhen (CN)

(72) Inventors: Ziyi Yang, Shenzhen (CN); Zhan Zhang, Shenzhen (CN)

(21) Appl. No.: 19/673,291

(22) Filed: May 11, 2026

(30) Foreign Application Priority Data
May 14, 2025 (CN) 202510622074.7

(51) Int. Cl. G03F 1/36; G03F 7/00

(52) U.S. Cl. CPC G03F 1/36; G03F 7/70441; G03F 7/705

(57) ABSTRACT

The present application discloses a mask pattern optimization method, an electronic device, and a program product. The method comprises determining a target optimization model from a plurality of optimization models based on an optimization accuracy requirement, the optimization models being obtained by training a design layout and a ridge point pattern with consistency; inputting a first design layout to the target optimization model to obtain a model prediction result; determining a ridge point pattern based on the model prediction result and the first design layout, the ridge point pattern comprising a plurality of ridge points containing direction information; and generating a first mask pattern based on the first design layout and the ridge points. In the present application, the mask patterns after ILT optimization have data consistency. An appropriate optimization model may be selected based on an optimization accuracy to ensure balance between calculation complexity and model accuracy.

### CROSS-REFERENCE TO RELATED APPLICATION

The present application claims priority to Chinese Patent Application No. 202510622074.7 filed on May 14, 2025, and titled “MASK PATTERN OPTIMIZATION METHOD, ELECTRONIC DEVICE, AND PROGRAM PRODUCT”, which is incorporated herein by reference in its entirety.

### TECHNICAL FIELD

The present application relates to the technical field of lithography, and in particular to a mask pattern optimization method, an electronic device, and a program product.

### BACKGROUND

In the field of integrated circuit design and manufacturing, Inverse Lithography Technology (ILT) is an important technology, which may optimize a mask pattern based on a designed chip circuit pattern, such that a pattern formed after light emitted by a light source irradiating on photoresist through a mask may fit with an originally designed chip circuit pattern.

According to the ILT technology, the mask pattern needs to be optimized as a whole, which consumes a lot of calculation resources and time resources. In related technologies, a combination of deep learning and ILT technology is adopted. That is, an original design layout and an optimized mask pattern are used as input and output of a training set to train a neural network model, and to predict a pattern of each design layout through a trained model.

However, in the process of pattern optimization of ILT technology, for two completely identical local circuit patterns, the optimized local mask patterns are not completely consistent. That is, for the identical local design layouts, the data after ILT optimization are not completely consistent and lack data consistency, which greatly increases a model training difficulty.

### SUMMARY

Embodiments of the present application provide a mask pattern optimization method, an electronic device, and a program product, which may mitigate the technical problem in the related art, that is, a mask pattern after ILT optimization lacks data consistency.

In a first aspect, embodiments of the present application provide a mask pattern optimization method, which comprises: determining a target optimization model from a plurality of optimization models based on an optimization accuracy requirement, the optimization models are obtained by training a design layout and a ridge point pattern with consistency; inputting a first design layout to the target optimization model to obtain a model prediction result; determining a ridge point pattern based on the model prediction result and the first design layout, the ridge point pattern comprises a plurality of ridge points containing direction information; and generating a first mask pattern based on the first design layout and the ridge points.

Optionally, before the determining a target optimization model from a plurality of optimization models based on an optimization accuracy requirement, the method further comprises: simulating, for a plurality of design layouts, a main graphic of a design layout combining with placed evaluation points to obtain an assist image formed based on the evaluation points in a case where an exposure graphic contour obtained by simulation satisfies a verification condition; determining a plurality of ridge points and corresponding ridge directions from the assist image; determining a first segment of the main graphic corresponding to each of the ridge points to obtain a correspondence relationship between the ridge point and the first segment, the first segment is a portion of an edge of the main graphic; performing traversal calculation on each first segment of the main graphic, and grouping first segments with a same traversal result to a same group; adjusting a ridge point corresponding to each first segment in each group such that a relative positional relationship between each first segment in a same group and a corresponding ridge point is consistent; and training, at different rendering resolutions, preset models taking rendered main graphics as input parameters and rendered mixed patterns as output parameters to obtain optimization models at different resolutions, the mixed patterns are formed by superimposing the rendered main graphics and rendered ridge point patterns, and the ridge point pattern comprises a plurality of ridge points containing direction information.

Optionally, the simulating a main graphic of a design layout combining with placed evaluation points to obtain an assist image formed based on the evaluation points in a case where an exposure graphic contour obtained by simulation satisfies a verification condition comprises: placing sub-resolution assist feature points around a main graphic of a design layout; inputting the main graphic and the sub-resolution assist feature points to a simulation model to obtain an exposure graphic contour; adjusting, in a case where the exposure graphic contour does not match a verification pattern contour, the sub-resolution assist feature points and re-inputting them to the simulation model until the exposure graphic contour matches the verification pattern contour; and generating a sub-resolution assist image based on the sub-resolution assist feature points satisfying a verification condition.

Optionally, the determining a plurality of ridge points and corresponding ridge directions from the assist image comprises: pixelating the sub-resolution assist image to obtain an original pixel matrix; performing gradient processing on the original pixel matrix to obtain a first-order gradient value image; determining a local peak point as a ridge point from the first-order gradient value image; and selecting, based on a second-order gradient of the original pixel matrix, a direction with a largest second-order gradient value around each ridge point as a ridge direction.

Optionally, the determining a first segment of the main graphic corresponding to each of the ridge points to obtain a correspondence relationship between the ridge point and the first segment comprises: determining, for each of the ridge points, one of the first segments with a closest distance to the ridge point in the main graphic; and constructing the correspondence relationship between the ridge point and the first segment with the closest distance.

Optionally, the performing traversal calculation on each first segment in the main graphic, and grouping the first segments with a same traversal result to a same group comprises: traversing each first segment of the main graphic to obtain adjacent first segments within a preset range of a first segment; calculating a sum of mapping values of adjacent first segments of each first segment as an eigenvalue of each first segment; and grouping the first segments with a same eigenvalue to the same group.

Optionally, the adjusting a ridge point corresponding to each first segment in each group comprises: selecting, for each group, one from a plurality of first segments in the group as a sample segment; and moving a ridge point corresponding to the sample segment, according to a movement trajectory from the sample segment to another first segment, to a corresponding position of another first segment, and updating a correspondence relationship between another first segment and the ridge point.

Optionally, the selecting, for each group, one from a plurality of first segments in the group as a sample segment comprises: acquiring position information of a center point of the sub-resolution assist image; calculating, for each group, a distance of each first segment in the group from the center point; and selecting a first segment having a shortest distance from the center point as a sample segment.

Optionally, the training, at different rendering resolutions, preset models taking rendered main graphics as input parameters and rendered mixed patterns as output parameters to obtain optimization models at different resolutions comprises: constructing preset models at different rendering resolutions; and generating, for each rendering resolution, a training set at a corresponding rendering resolution, and training the training set using a preset model to obtain a corresponding optimization model, input parameters of the training set are rendered main graphics of the plurality of design layouts, and output parameters are mixed patterns formed by superimposing the rendered main graphics of the plurality of design layouts and rendered ridge point patterns.

Optionally, the determining a ridge point pattern based on the model prediction result and the first design layout comprises: calculating a difference between the model prediction result and the first design layout to obtain a prediction ridge point pattern corresponding to the first design layout; and performing data processing on the prediction ridge point pattern to obtain a plurality of ridge points and corresponding ridge directions and determine a ridge point pattern.

In a second aspect, embodiments of the present application provide a mask pattern optimization device, which comprises: a determination module, configured to determine a target optimization model from a plurality of optimization models based on an optimization accuracy requirement, the optimization models are obtained by training a design layout and a ridge point pattern with consistency; a model prediction module, configured to input a first design layout to the target optimization model to obtain a model prediction result; a ridge point extraction module, configured to determine a ridge point pattern based on the model prediction result and the first design layout, the ridge point pattern comprises a plurality of ridge points containing direction information; and a pattern optimization module, configured to generate a first mask pattern based on the first design layout and the ridge points.

In a third aspect, embodiments of the present application provide an electronic device, which comprises a processor and a memory storing computer program instructions, the processor, when executes the computer program instructions, carries out steps of the mask pattern optimization method according to the first aspect.

In a fourth aspect, embodiments of the present application provide a computer-readable storage medium storing computer program instructions, the computer program instructions, when executed by a processor, carry out steps of the mask pattern optimization method according to the first aspect.

In a fifth aspect, embodiments of the present application provide a computer program product comprising computer program, instructions in the computer program product, when executed by a processor, carry out steps of the mask pattern optimization method according to the first aspect.

In the mask pattern optimization method, the electronic device, and the program product according to the embodiments of the present application, different optimization models are pre-trained based on different optimization accuracy requirements. Each of the optimization models is trained based on the design layout and the ridge point pattern with consistency. For the first design layout that needs to be optimized, the first design layout may be input to the target optimization model to obtain the model prediction result. After obtaining the ridge points based on the model prediction result and the first design layout, ILT may be performed on the first design layout combining with the ridge points to obtain the first mask pattern. Since the training sets input in the model training process satisfy the data consistency, for the local identical design layouts in the first design layout, it may be ensured that, the local mask patterns in the first mask pattern corresponding to the local identical design layouts keep consistency, such that the mask pattern after ILT optimization has data consistency. Moreover, according to different optimization accuracy requirements, an appropriate optimization model may be selected according to an actual needed rendering resolution to avoid the problem of excessive consumption of calculation resources caused by too high rendering resolution, and achieve balance between calculation complexity and model accuracy.

### BRIEF DESCRIPTION OF THE DRAWINGS

In order to explain the technical solutions of the embodiments of the present application more clearly, a brief introduction to the drawings for the embodiments of the present application will be provided below. For a person skilled in the art, additional drawings may be derived from these drawings without inventive efforts.

FIG. 1 shows a flow chart of a mask pattern optimization method according to an embodiment of the present application;

FIG. 2 shows a partial flow chart of a mask pattern optimization method according to an embodiment of the present application;

FIG. 3 shows a partial flow chart of a mask pattern optimization method according to another embodiment of the present application;

FIG. 4 shows a partial flow chart of a mask pattern optimization method according to yet another embodiment of the present application;

FIG. 5 shows a schematic view of pixel brightness of an original pixel matrix according to an embodiment of the present application;

FIG. 6 shows a schematic view of pixel brightness of a first-order gradient value image according to an embodiment of the present application;

FIG. 7 shows a schematic view of pixel brightness of a second-order gradient value image according to an embodiment of the present application;

FIG. 8 shows a partial flow chart of a mask pattern optimization method according to yet another embodiment of the present application;

FIG. 9 shows a schematic view of a partial pattern of a design layout and corresponding ridge points according to an embodiment of the present application;

FIG. 10 shows a schematic view of a partial pattern of a design layout and corresponding ridge points according to another embodiment of the present application;

FIG. 11 shows a schematic structural view of a mask pattern optimization device according to still another embodiment of the present application; and

FIG. 12 shows a schematic structural view of an electronic device according to yet another embodiment of the present application.

### DETAILED DESCRIPTION

Features and exemplary embodiments of various aspects of the present application will be described in detail below. In order to make the objects, technical solutions and advantages of the present application more clear, the present application will be further described in detail below with reference to the drawings and specific embodiments. It should be understood that, the specific embodiments described herein are only intended to explain the present application, but not to limit the present application. For those of ordinary skilled in the art, the present application may be implemented without some of those specific details. The following description of the embodiments is only for providing a better understanding of the present application by showing examples.

It should be noted that, relational terms such as first, second, and the like are used herein merely for distinguishing one entity or operation from another without necessarily requiring or implying any such actual relationship or order between such entities or operations. Moreover, the terms “include”, “comprise”, or any other variation thereof, are intended to cover a non-exclusive inclusion, such that a(n) process, method, article or device that includes a series of elements not only includes those elements but also includes other elements not explicitly listed or also includes elements inherent to such process, method, article or device. An element preceded by “include…” does not, without more constraints, preclude the existence of additional identical elements in the process, method, article or device that includes the element.

In the field of integrated circuit design and manufacturing, ILT is an important technology, which may optimize a mask pattern based on a designed chip circuit pattern, such that a pattern formed after light emitted by a light source irradiating on photoresist through a mask may fit with an originally designed chip circuit pattern.

According to the ILT technology, the mask pattern needs to be optimized as a whole, which consumes a lot of calculation resources and time resources. In related technologies, a combination of deep learning and ILT technology is adopted. That is, an original design layout and an optimized mask pattern are used as input and output of a training set to train a neural network model, and to predict a pattern of each design layout through a trained model.

However, in the process of pattern optimization of ILT technology, for two completely identical local circuit patterns, the optimized local mask patterns are not completely consistent. That is, for the identical local design layouts, the data after ILT optimization is not completely consistent and lacks data consistency, which greatly increases a model training difficulty.

In related technologies, in order to solve the problem that the data after ILT optimization lacks consistency, which causes high model training difficulty, a method of adding an additional auxiliary training model is adopted. The auxiliary training model may simulate and predict a pattern finally formed on a wafer based on a mask pattern. For an original prediction model, it includes two pieces of supervision information, in which a first one is that, for an input design layout, it requires that a mask pattern predicted and output by a prediction model is close to an actual output corresponding to sample data in a training set, that is, close to an actual mask pattern in the sample data; and a second one is that, for the mask pattern predicted and output by the prediction model, it requires that a pattern formed on a wafer obtained by simulation and prediction of the auxiliary training model is also close to the design layout.

In the above technical solution, in order to solve the problem of high model training difficulty, an auxiliary training model is introduced. After introducing the auxiliary training model, the prediction model will not require that a unique mask pattern is predicted based on the identical design layout, but it only requires that a predicted mask pattern, after simulation and prediction of the auxiliary training model, is close to the design layout. However, in the aforesaid technical solution, for the identical design layout, the mask pattern predicted by the prediction model is still not unique. Therefore, during the model training process, the problem of data inconsistency of predicted data still cannot be solved, which greatly reduces a model convergence rate and seriously affects a model training efficiency.

In order to solve at least one of the aforesaid technical problems, embodiments of the present application provide a mask pattern optimization method, an electronic device, and a program product. First, the mask pattern optimization method provided by the embodiments of the present application will be described below.

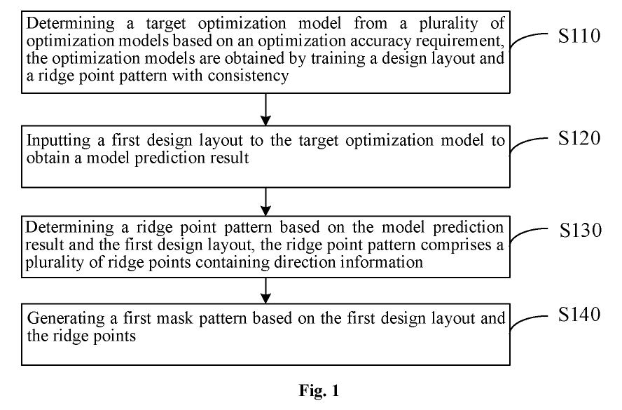

FIG. 1 shows a flow chart of a mask pattern optimization method according to an embodiment of the present application. The method may include the steps of:

S110, determining a target optimization model from a plurality of optimization models based on an optimization accuracy requirement, the optimization models are obtained by training a design layout and a ridge point pattern with consistency;

S120, inputting a first design layout to the target optimization model to obtain a model prediction result;

S130, determining a ridge point pattern based on the model prediction result and the first design layout, the ridge point pattern includes a plurality of ridge points containing direction information; and

S140, generating a first mask pattern based on the first design layout and the ridge points.

In this embodiment, different optimization models are pre-trained based on different optimization accuracy requirements. Each of the optimization models is trained based on the design layout and the ridge point pattern with consistency. For the first design layout that needs to be optimized, the first design layout may be input to the target optimization model to obtain the model prediction result. After obtaining the ridge points based on the model prediction result and the first design layout, ILT may be performed on the first design layout combining with the ridge points to obtain the first mask pattern. Since the training set input in the model training process satisfies the data consistency, for the local identical design layout in the first design layout, it may be ensured that, the local mask pattern in the first mask pattern corresponding to the local identical design layout keeps consistency, such that the mask pattern after ILT optimization has data consistency. Moreover, according to different optimization accuracy requirements, an appropriate optimization model may be selected according to an actual needed rendering resolution to avoid the problem of excessive consumption of calculation resources caused by too high rendering resolution, and achieve balance between calculation complexity and model accuracy.

The specific implementation of each of the above steps will be described below.

In S110, based on the optimization accuracy requirements at different resolutions, a plurality of optimization models may be pre-trained and generated, and each of the optimization models may correspond to an optimization accuracy requirement at one resolution. An input parameter of each of the optimization models may include a design layout, and an output parameter may include the design layout and a ridge point pattern with consistency.

In the case that there are a plurality of completely identical local patterns in a design layout, since the ridge point patterns required in the ILT optimization process are consistent, the mask patterns corresponding to each of the local patterns after optimization by ILT technology may keep consistent, thus ensuring the data consistency of the mask patterns after LIT optimization.

Before optimizing a first design layout provided by a user, an appropriate target optimization model may be determined from a plurality of optimization models according to an optimization accuracy requirement selected by the user. Then, the target optimization model is used for optimizing the mask pattern, which may meet the accuracy requirement without producing excessive calculation complexity, that is, it may achieve balance between calculation complexity and model accuracy.

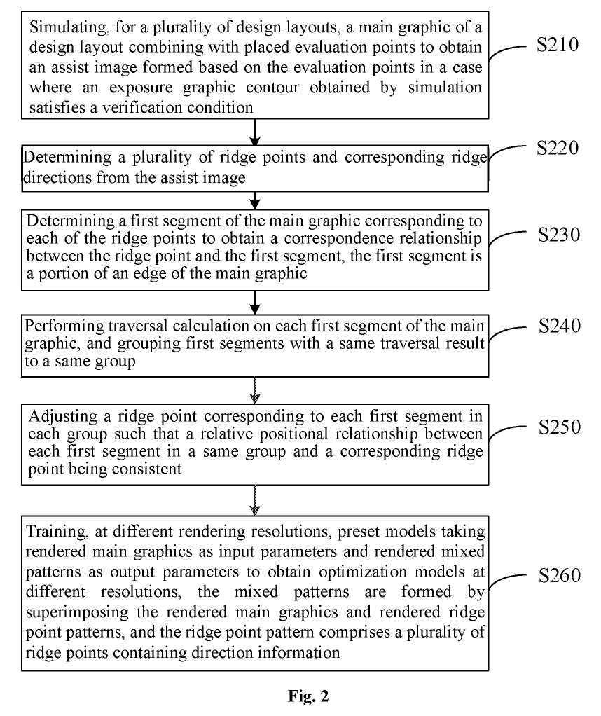

Referring to FIG. 2, in some embodiments, before S110, the method may further include steps of:

S210, simulating, for a plurality of design layouts, a main graphic of the design layout combining with placed evaluation points to obtain an assist image formed based on the evaluation points in a case where an exposure graphic contour obtained by simulation satisfies a verification condition;

S220, determining a plurality of ridge points and corresponding ridge directions from the assist image;

S230, determining a first segment of the main graphic corresponding to each of the ridge points to obtain a correspondence relationship between the ridge point and the first segment, the first segment is a portion of an edge of the main graphic;

S240, performing traversal calculation on each first segment of the main graphic, and grouping first segments with a same traversal result to a same group;

S250, adjusting a ridge point corresponding to each first segment in each group such that a relative positional relationship between each first segment in a same group and a corresponding ridge point is consistent; and

S260, training, at different rendering resolutions, preset models taking rendered main graphics as input parameters and rendered mixed patterns as output parameters to obtain optimization models at different resolutions, the mixed patterns are formed by superimposing the rendered main graphics and rendered ridge point patterns, and the ridge point pattern includes a plurality of ridge points containing direction information.

Before performing mask pattern optimization using an optimization model, model training may be performed by the implementations described in the following embodiments to obtain the optimization model.

In this embodiment, for a plurality of design layouts, a corresponding assist image may be obtained based on the main graphic of each of the design layouts through simulation and verification. A correspondence relationship may be constructed between each ridge point in the assist image and the first segment of the main graphic. Traversal calculation may be performed on each first segment of the main graphic, and first segments with a same traversal result are grouped to a same group. It is maintained that, the first segments in a same group have a same ridge point, that is, a relative positional relationship between each first segment in a same group and a corresponding ridge point is consistent. When mask patterns for the first segments in the same group are generated, since each first segment in the same group has a same ridge point, it may be ensured that the mask patterns correspondingly generated based on the same first segments are consistent, thereby ensuring data consistency in the local design. The main graphic and the ridge point pattern may be rendered at different rendering resolutions, and paired data composed of the main graphic and the mixed pattern may be used as a training set to train the model to obtain the optimization models at different rendering resolutions. Since the training set input to the model meets the data consistency, it greatly reduces a data fitting difficulty of the deep learning model.

In S210, in the model training process, a plurality of design layouts may be selected as samples for model training. For a plurality of existing design layouts, one single design layout will be described below as an example.

For one of the plurality of design layouts, evaluation points may be placed around the main graphic of the design layout, and the main graphic and the placed evaluation points may be input to a simulation model for simulation to obtain an exposure graphic contour output after simulation. After the exposure graphic contour is obtained, it may be compared with a verification condition to determine whether the obtained exposure graphic contour sufficiently fits with a verification pattern contour, that is, whether the exposure graphic contour meets the requirement.

In a case where the exposure graphic contour obtained by simulation satisfies the verification condition, a corresponding assist image may be formed according to the evaluation points placed at this time.

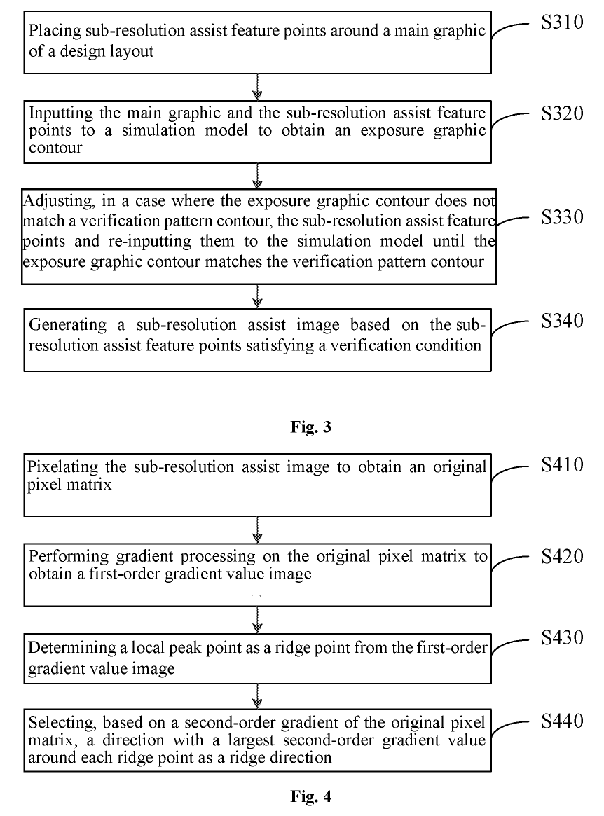

Referring to FIG. 3, in some embodiments, the aforesaid S210 may include sub-steps of:

S310, placing sub-resolution assist feature points around the main graphic of the design layout;

S320, inputting the main graphic and the sub-resolution assist feature points to a simulation model to obtain an exposure graphic contour;

S330, adjusting, in a case where the exposure graphic contour does not match a verification pattern contour, the sub-resolution assist feature points and re-inputting them to the simulation model until the exposure graphic contour matches the verification pattern contour; and

S340, generating a sub-resolution assist image based on the sub-resolution assist feature points satisfying a verification condition.

In this embodiment, after the sub-resolution assist feature points are placed around the main graphic of the design layout, simulation calculation may be performed to obtain the exposure graphic contour. By continuously adjusting the sub-resolution assist feature points, the exposure graphic contour may sufficiently fit with the verification pattern contour, and a sub-resolution assist image may be generated based on the sub-resolution assist feature points at this time.

In S310, Sub-Resolution Assist Feature (SRAF) points, hereinafter referred to as SRAF points, may be placed around the main graphic of the design layout according to relevant rules. The main graphic refers to a main graphic contour in the design layout, which usually represents a basic shape and characteristics of a chip circuit. For example, the main graphic typically includes important components, such as transistors, connection wires, resistors, which mainly appears as two-dimensional geometry. During a lithography process, the main graphic needs to be accurately transferred to a silicon wafer to ensure a functionality and performance of a chip.

SRAF points are specific measurement points set near a main graphic boundary during the lithography process. The SRAF points may be used for evaluating a relationship between the main graphic and a corresponding sub-resolution assist pattern and an optimization effect thereof.

In S320, after the SRAF points are placed, the main graphic and the SRAF points may be input to the simulation model together to obtain the simulation result, that is, the exposure graphic contour of the main graphic.

In S330, after the exposure graphic contour is obtained in the simulation calculation process of the simulation model, the exposure graphic contour may be compared with the verification pattern contour. If the exposure graphic contour does not fit well with the verification pattern contour, it means that the SRAF points need to be adjusted. In this case, an intensity value or other parameters of the SRAF points may be adjusted to realize the adjustment of the SRAF points. For example, the intensity value may be understood as a light intensity of light emitted by a light source at a particular point, such as the main graphic or SRAF points. In the lithography process, the light intensity at different positions will vary due to an intensity of the light source, a propagation path of the light, refraction, reflection and other factors. The light intensity directly affects a chemical reaction of the photoresist. For example, excessively high light intensity may lead to overexposure, which affects a sharpness and shape of pattern edges; while, insufficient light intensity may lead to incomplete development of the pattern. Therefore, by adjusting the intensity value of the SRAF points, parameters such as shape and intensity of the sub-resolution assist image may be optimized to improve the exposure graphic contour in the lithography process and make it more fit with the verification pattern contour.

After the SRAF points are adjusted, simulation may be performed continuously based on the main graphic and the adjusted SRAF points.

In the simulation and optimization process of the sub-resolution assist image based on the intensity value of the SRAF points, a shape width, space, or other geometric parameters of positions corresponding to the SRAF points in the sub-resolution assist image may be adjusted according to the adjusted intensity value. For example, according to the adjusted intensity value of the SRAF points, a shape of a corresponding position in the sub-resolution assist image may be optimized by techniques such as geometric transformation and segment weighting to obtain an optimized sub-resolution assist image. Then, the main graphic and the optimized sub-resolution assist image may be superimposed, and an optimized exposure graphic contour may be obtained by simulation calculation.

By continuously performing the simulation-adjustment cycling process, the cycling process may be stopped in the case that the exposure graphic contour matches the verification pattern contour, that is, the exposure graphic contour sufficiently fits with the verification pattern contour.

In S340, in the case that the exposure graphic contour matches the verification pattern contour, the current SRAF points may be determined as the SRAF points satisfying the verification condition. Based on the SRAF points satisfying the verification condition, a sub-resolution assist image, hereinafter referred to as an SRAF image, may be generated.

In S220, after the assist image is obtained, the assist image may be processed, and a plurality of ridge points and a ridge direction of each ridge point may be determined based on a processing result.

Referring to FIG. 4, in some embodiments, the aforesaid S220 may include sub-steps of:

S410, pixelating the sub-resolution assist image to obtain an original pixel matrix;

S420, performing gradient processing on the original pixel matrix to obtain a first-order gradient value image;

S430, determining a local peak point as a ridge point from the first-order gradient value image; and

S440, selecting, based on a second-order gradient of the original pixel matrix, a direction with a largest second-order gradient value around each ridge point as a ridge direction.

In this embodiment, after the pixelation processing and the gradient processing are performed on the SRAF image, a peak point of each local position may be selected as the ridge point based on the gradient value of each pixel position. For the original pixel matrix after the pixelation processing, the ridge direction of each ridge point may be determined based on the second-order gradient value.

In S410, after the SRAF image is obtained, the SRAF image may be pixelated to obtain the original pixel matrix.

As an optional embodiment, taking an example that the main graphic includes 16 quadrilaterals arranged in a 4 * 4 array, after the SRAF image corresponding to the 16 quadrilaterals is obtained by the above embodiments, the SRAF image may be pixelated to obtain the original pixel matrix shown in FIG. 5.

In the original pixel matrix shown in FIG. 5, among the 16 quadrilaterals, one single quadrilateral corresponds to a pixel region polygon composed of n * n pixels in the original pixel matrix. The pixel points around each pixel region may correspond to each of the SRAF points in the SRAF image one-to-one. A brightness value of each pixel point may represent parameter information of the corresponding SRAF point, for example, may represent an intensity value of the SRAF point.

In S420, after gradient processing is performed on the original pixel matrix once, a gradient value image corresponding to the original pixel matrix may be obtained.

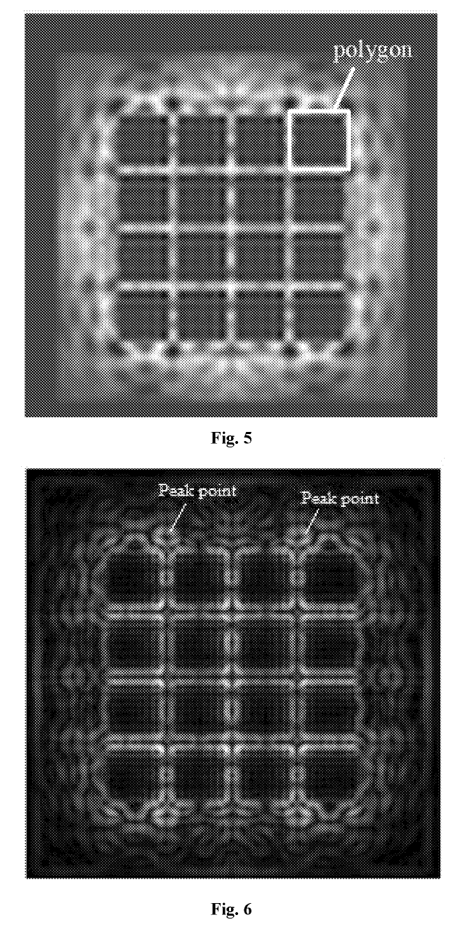

Referring to FIG. 6, based on the original pixel matrix shown in FIG. 5, gradient processing is performed on each pixel point once to obtain a first-order gradient value image shown in FIG. 6. The first-order gradient value of each pixel point may represent a change direction and a change rate of the brightness value of the pixel point. In the first-order gradient value image shown in FIG. 6, the brightness value of each pixel point may represent a first-order gradient value corresponding to a SRAF point.

In S430, in the first-order gradient value image, a plurality of pixel points having a relatively larger brightness value in a local range may be selected as peak points according to the brightness value corresponding to each pixel point, and the plurality of finally obtained peak points may serve as a plurality of ridge points.

The peak points may be acquired by setting a domain range in advance, and for each pixel point in the first-order gradient value image, it may be determined, in the domain range of each pixel point, whether there are other pixels with a brightness value higher than the brightness value of the pixel point. If there is no other pixel point with higher brightness value in a domain range of a certain pixel point, the pixel point may serve as a peak point in the local range. As shown in FIG. 6, after the first-order gradient value of a certain pixel point is determined, if the first-order gradient values of other pixel points in the domain range of the pixel point do not exceed the first-order gradient value of the pixel point, the pixel point may serve as a peak point. At last, a plurality of peak points may be obtained from the first-order gradient value image and may serve as a plurality of ridge points.

It should be noted that, a number of the peak points may be adjusted by adjusting a size of the domain range. When more ridge points are needed, the size of the domain range may be decreased to screen out more peak points as ridge points; while when fewer ridge points are needed, the size of the domain range may be increased to screen out less peak points as ridge points.

As an optional embodiment, the domain range may be a range formed by a plurality of pixel points whose distance from a certain pixel point is within a preset distance; alternatively, the domain range may be a range formed by all pixel points in a certain direction with a certain pixel point as a reference position. For example, taking a certain pixel point as a reference position, all pixel points in one direction, for example the upper and lower directions, of the pixel point may be pixel points above the pixel point and pixel points below the pixel point. In the case that a brightness value of at least one of the upper pixel points and the lower pixel points is higher than a brightness value of the pixel point at the reference position, the pixel point is not a peak point. On the contrary, if brightness values of all pixel points in the upper pixel points and the lower pixel points are lower than the brightness value of the pixel point, the pixel point is a peak point.

Based on a correspondence relationship between the pixel point coordinates serving as peak points and the SRAF points in the original pixel matrix, the position coordinates of the partial SRAF points serving as ridge points may be determined from the plurality of SRAF points.

In S440, after the position coordinates of each ridge point are determined, a second gradient processing may be performed on the original pixel matrix to obtain a second-order gradient value image of the original pixel matrix. According to the position coordinates of each ridge point, a direction with a largest second-order gradient value around each ridge point may be selected as a ridge direction corresponding to the ridge point.

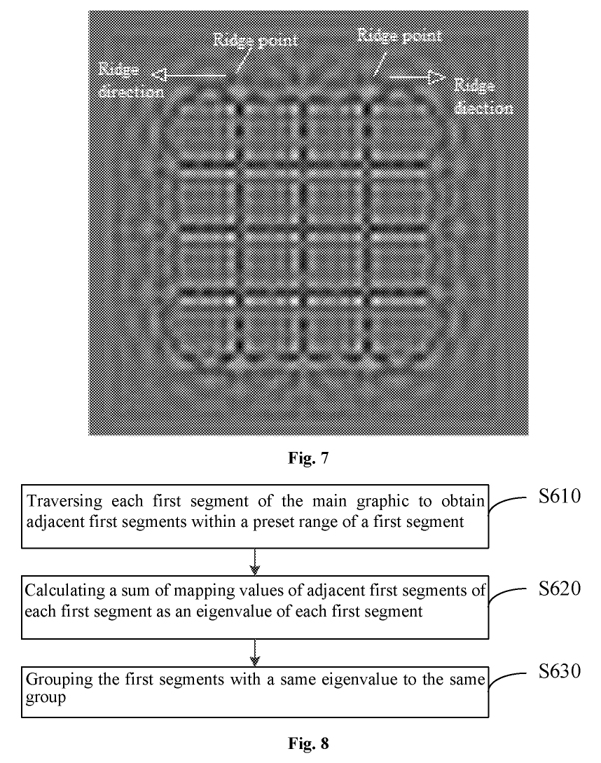

Referring to FIG. 7, based on the first-order gradient value image shown in FIG. 6, gradient processing is performed on the brightness value of each pixel point again to obtain the second-order gradient value image shown in FIG. 7. In the second-order gradient value image shown in FIG. 7, the brightness value of each pixel point may represent the second-order gradient value corresponding to the SRAF point.

In the second-order gradient value image, according to the coordinates of the peak points which are selected as the ridge points, a plurality of pixel points adjacent to each ridge point around the ridge point may be determined, and the brightness values of the plurality of pixel points may be obtained. For example, there may be eight adjacent pixel points around each ridge point.

After the brightness values of the plurality of pixel points adjacent to the ridge point are obtained, a pixel point with a highest brightness value may be determined, and a direction from the ridge point to the pixel point with the highest brightness value may be determined as the ridge direction.

In S230, based on each ridge point, a first segment corresponding to a ridge point may be determined from all the first segments of the main graphic. After the first segment corresponding to the ridge point is determined, a correspondence relationship between the ridge point and the first segment may be generated. The first segment may be a portion of an edge of the main graphic.

In some embodiments, the aforesaid S230 may include sub-steps of:

S510, setting a plurality of breakpoints on each edge of the main graphic;

S520, dividing each edge of the main graphic into a plurality of first segments based on the plurality of breakpoints;

S530, determining, for each ridge point, a first segment with a closest distance to the ridge point from the main graphic; and

S540, constructing a correspondence relationship between the ridge point and the first segment with a closest distance.

In this embodiment, after the plurality of ridge points are determined, each edge of the main graphic may be divided into a plurality of first segments, and the first segment with a closest distance to each ridge point may be determined from the main graphic as the first segment corresponding to the ridge point, and then a correspondence relationship between the ridge point and the first segment may be constructed.

In S510, for each edge of the main graphic, a plurality of breakpoints may be set on the edge. The setting rules of the breakpoints may be prescribed in advance, such as a maximum distance and a minimum distance between breakpoints, among others.

In S520, each edge of the main graphic may be divided into a plurality of first segments with a shorter length based on the plurality of breakpoints provided on each edge.

In S530, for each ridge point, a distance between each first segment of the main graphic and the ridge point may be calculated, and a first segment with a closest distance to the ridge point may be selected from the plurality of first segments as the first segment corresponding to the ridge point.

In S540, after the first segment corresponding to each ridge point is determined, a correspondence relationship between the ridge point and the first segment with a closest distance may be constructed.

In S240, for the main graphic of the design layout, traversal calculation may be performed on each first segment of the main graphic. For the traversed first segment, a traversal result may be generated based on a preset algorithm. After the traversal calculation is completed, the first segments with a same traversal result may be grouped to a same group.

Referring to FIG. 8, in some embodiments, the aforesaid S240 may include sub-steps of:

S610, traversing each first segment of the main graphic to obtain adjacent first segments within a preset range of a first segment;

S620, calculating a sum of mapping values of adjacent first segments of each first segment as an eigenvalue of each first segment; and

S630, grouping the first segments with a same eigenvalue to the same group.

In this embodiment, when the first segment of the main graphic is traversed, the adjacent first segments of each first segment may be determined, and the mapping values of the adjacent first segments may be calculated, and then the sum of the mapping values may serve as the eigenvalue of the first segment. After the eigenvalues of all of the first segments are calculated, the first segments with a same eigenvalue may be grouped into the same group. In this case, the first segments in the same group may be regarded as partially identical first segments.

In S610, when each first segment of the main graphic is traversed, a preset range may be determined in advance, and for each first segment, other first segments existing within the preset range of the first segment may be determined and used as adjacent first segments to the traversed first segment.

It may be understood that, if there is no other first segment within the preset range of a certain first segment, the number of adjacent first segment within the preset range of the first segment is 0.

In S620, in the traversal process, if there is at least one adjacent first segment within a preset range of a certain first segment, a mapping value of the adjacent first segment may be calculated based on a preset algorithm. If a certain first segment has a plurality of adjacent first segments, mapping values of the respective adjacent first segments may be calculated, and then a sum of the mapping values may be obtained. The sum of the mapping values may serve as the eigenvalue of the traversed first segment.

As an optional embodiment, the preset algorithm may be a hash algorithm, and for each adjacent first segment, a corresponding hash value may be calculated based on the hash algorithm as the mapping value.

It may be understood that, if a certain first segment does not have an adjacent first segment, the eigenvalue of the first segment is 0. If a certain first segment has only one adjacent first segment, the mapping value of the adjacent first segment is the eigenvalue of the first segment.

In S630, after all of the first segments are traversed, the first segments may be grouped according to the eigenvalue of each first segment, and the first segments with a same eigenvalue may be grouped to the same group.

It may be understood that, if the eigenvalues of any two first segments are the same, it means that the adjacent first segments of the two first segments are the same, and the two first segments have an identical local design. Therefore, a plurality of first segments grouped to a same group may all be regarded as the identical local design.

In S250, after the first segments of the main graphic are grouped according to the traversal result, for the plurality of first segments in each group, a ridge point corresponding to each first segment may be adjusted such that a relative positional relationship between each first segment in a same group and a corresponding ridge point is consistent.

It should be noted that, “the relative positional relationship between each first segment in a same group and a corresponding ridge point is consistent” does not mean that the first segments all correspond to one ridge point, but that a distance and positional relationship between each first segment and it corresponding ridge point is consistent. For example, two first segments a and b in the same group correspond to ridge points x and y, respectively. If a relative position and a distance between the first segment a and the ridge point x is consistent with a relative position and a distance between the first segment b and the ridge point y, then the first segment a and the first segment b correspond to the same ridge point. That is, the ridge points corresponding to the first segments other than a sample segment in the same group are changed to the same ridge point as the sample segment by symmetry analysis.

In some embodiments, the aforesaid S250 may include sub-steps of:

S710, selecting, for each group, one from a plurality of first segments in the group as a sample segment; and

S720, moving a ridge point corresponding to the sample segment, according to a movement trajectory from the sample segment to another first segment, to a corresponding position of another first segment, and updating a correspondence relationship between another first segment and the ridge point.

In this embodiment, one first segment may be selected from the first segments in the same group as the sample segment, and the ridge points corresponding to other first segments may be updated based on the ridge point corresponding to the sample segment, such that each of the first segments in the same group has the same ridge point.

In S710, for each group after grouping, one first segment is selected from a plurality of first segments in the group as a sample segment. By adjusting the ridge point corresponding to another first segment in the following embodiments, the correspondence relationship between another first segment and the ridge point may be made consistent with the correspondence relationship between the sample segment and the ridge point.

In some embodiments, the aforesaid S710 may include sub-steps of: acquiring position information of a center point of the sub-resolution assist image; calculating, for each group, a distance of each first segment in the group from the center point; and selecting a first segment having a shortest distance from the center point as a sample segment.

In this embodiment, when the sample segment is selected from the plurality of first segments in each group, position information of the center point of the SRAF image may be acquired in advance. For each group, when the sample segment is selected, the distance of each first segment in the group from the center point may be calculated. After the position information of the first segment and the position information of the center point of the SRAF image are obtained, the distance between the first segment and the center point may be calculated based on a distance algorithm. After the distance between each first segment and the center point are determined, the first segment having the shortest distance from the center point may be selected as the sample segment.

It may be understood that, after the distance between each first segment and the center point are determined, if the first segment having the shortest distance from the center point does not have a corresponding ridge point, a filtering process may be further performed on the remaining first segments according to distance to obtain the first segment having the corresponding ridge point as the sample segment.

In S720, after the sample segment is determined, the ridge point corresponding to the sample segment may be moved to the corresponding position of another first segment according to the movement trajectory from the sample segment to another first segment. For example, after the relative position between the sample segment and the ridge point is determined, for another first segment in the same group, a movement trajectory from the sample segment to a certain first segment may be determined, and the sample segment may be moved based on the movement trajectory to coincide with the certain first segment. For the ridge point corresponding to the sample segment, a same ridge point may be copied at an original position and moved according to the same movement trajectory, and a relative positional relationship between the moved first segment and the moved ridge point is still consistent with a relative positional relationship between the sample segment and the original ridge point.

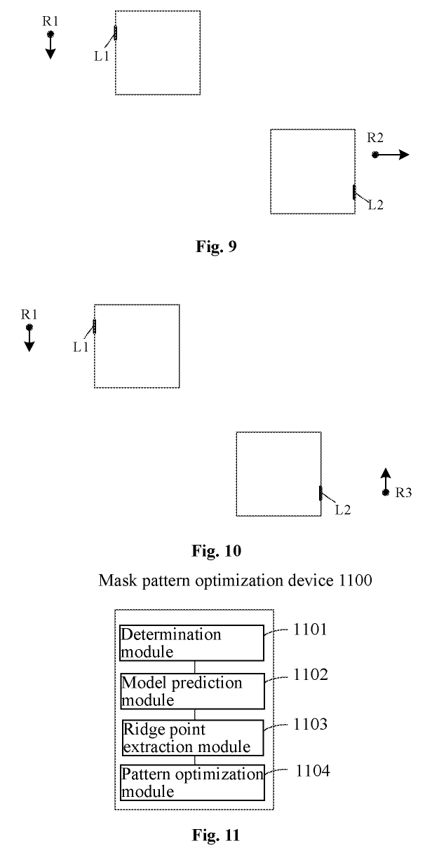

Referring to FIGS. 9 and 10, as an optional embodiment, taking a main graphic including 16 quadrilaterals arranged in a 4 * 4 array as an example, L1 is located on one edge of one quadrilateral, and L2 is located on one edge of the other quadrilateral. In the aforesaid traversal process, L1 and L2 have a same eigenvalue and may be grouped to a same group.

As shown in FIG. 9, after the grouping is completed, for two first segments L1 and L2 in the same group, the first segment L1 has a corresponding ridge point R1, and the first segment L2 has a corresponding ridge point R2. A relative positional relationship between the first segment L1 and the ridge point R1 is different from a relative positional relationship between the first segment L2 and the ridge point R2. Therefore, in a process of generating a mask pattern based on a design layout, if the mask pattern is directly generated based on the ridge point R1 and the ridge point R2, there will be difference between the two mask patterns respectively generated corresponding to the two first segments L1 and L2.

Based on the aforesaid embodiment, L1 may be selected as a sample segment, and the ridge point R1 may be copied, rotated and translated based on a movement trajectory from the first segment L1 to the first segment L2 to obtain a ridge point R3 as shown in FIG. 10.

After the ridge point R3 is obtained by copying, rotating and translating, the relative positional relationship between the first segment L1 and the ridge point R1 is consistent with a relative positional relationship between the first segment L2 and the ridge point R3. Therefore, in the subsequent process of generating the mask pattern based on the design layout, the two mask patterns respectively generated corresponding to the two first segments L1 and L2 may be kept consistent.

It should be noted that, in the process of ridge point adjustment, if a certain first segment, for example, the first segment L2, already has a corresponding ridge point before adjustment, after a new ridge point R3 corresponding to the first segment L2 is generated based on the relative positional relationship between the first segment L1 and the ridge point R1, it is necessary to delete or unbind the correspondence relationship between the first segment L2 and the ridge point R2. Accordingly, if a certain first segment does not have a corresponding ridge point, a new ridge point may be directly generated to correspond to the first segment.

In the case that a plurality of first segments are included in the same group, the ridge point corresponding to the sample segment may be moved to a corresponding position of another first segment by copying and moving according to the aforesaid embodiments, and a correspondence relationship between another first segment and an original ridge point may be adjusted to a correspondence relationship between the first segment and a moved ridge point. That is, if there is a ridge point corresponding to the first segment other than the sample segment, the originally corresponding ridge point may be updated to the moved ridge point.

According to the above embodiments, each first segment in the same group has the same ridge point, such that for the partially identical design layout in the main graphic, a consistent mask pattern may be obtained when ILT optimization is performed, which may mitigate the problem of lacking data consistency after ILT optimization.

In S260, according to the aforesaid embodiments, a plurality of ridge point patterns may be obtained for each design layout, and the corresponding ridge point patterns may be kept consistent for the identical local patterns.

Different rendering resolutions may be determined based on different optimization accuracy requirements. For each rendering resolution, a main graphic of a design layout may be rendered according to the resolution to obtain a rendered main graphic.

For each main graphic, a corresponding ridge point pattern may be generated according to a plurality of corresponding ridge points containing direction information. The position coordinates of each ridge point are included in the ridge point pattern, and at the position coordinates of the ridge point, the direction information of the ridge point may be represented by gray-scale values.

The ridge point pattern may be rendered according to the rendering resolution, and a rendered main graphic and a rendered ridge point pattern may be superimposed to form a mixed pattern.

In the aforesaid embodiments, the main graphic of each design layout has accurate coordinate information, and each ridge point in the ridge point pattern also has accurate coordinate information. After the appropriate rendering resolution is selected, the main graphic and the ridge point pattern may be rendered as input parameters and output parameters at the appropriate resolution to be input to a corresponding optimization model for training.

For each design layout, the rendered main graphic may be used as input parameters and the rendered mixed pattern may be used as output parameters to form a paired data. After a plurality of paired data corresponding to a plurality of design layouts respectively are obtained, the plurality of paired data may be used as a training set of a model to train a preset model and to obtain an optimization model at the resolution.

For different rendering resolutions, a plurality of paired data at each rendering resolution may be obtained by the aforesaid embodiments, and then the preset models may be trained respectively to obtain optimization models corresponding to different resolutions.

In some embodiments, the aforesaid S260 may include sub-steps of:

S810, constructing preset models at different rendering resolutions; and

S820, generating, for each rendering resolution, a training set at a corresponding rendering resolution, and training the training set using a preset model to obtain a corresponding optimization model, input parameters of the training set are rendered main graphics of the plurality of design layouts, and output parameters are mixed patterns formed by superimposing the rendered main graphics of the plurality of design layouts and rendered ridge point patterns.

In this embodiment, at different rendering resolutions, the rendered main graphics may be used as input parameters, and the rendered mixed patterns may be used as output parameters to form paired data, and a plurality of paired data of a plurality of design layouts may constitute a training set to train the model and to obtain an optimization model at a corresponding rendering resolution.

In S810, in the model training process, preset models at different rendering resolutions may be pre-constructed.

In S820, for each rendering resolution, a training set at the rendering resolution may be generated. The training set includes a plurality of paired data, in which input parameters of the paired data are rendered main graphics, and output parameters are mixed patterns formed by superimposing the rendered main graphics and rendered ridge point patterns.

For the training set at each rendering resolution, the preset model may be trained at this resolution to obtain the corresponding optimization model.

In S120, for the first design layout to be optimized, the design layout may be rendered according to the rendering resolution corresponding to the target optimization model, and then input the design layout to the target optimization model. The target optimization model may generate a model prediction result based on the input first design layout.

In S130, based on the aforesaid training process, when the first design layout is input, the model prediction result generated by the target optimization model is a mixed pattern. Then, comparative calculation is performed on the mixed pattern and the rendered main graphic of the first design layout to obtain the rendered ridge point pattern. The ridge point pattern includes the position coordinates of each ridge point and the ridge direction of each ridge point.

The ridge points in the ridge point pattern refer to a plurality of local peak points in a gradient value image obtained by performing gradient processing on the assist image generated based on the main graphic of the design layout combining the placed evaluation points. The ridge direction refers to a direction with a largest second-order gradient value among the eight directions of the ridge point after a second-order gradient processing is performed on the first-order gradient value image.

In the process of generating a corresponding mask pattern based on the design layout, for each pattern on the design layout, a corresponding mask pattern may be generated according to a ridge point in the ridge point pattern corresponding to a first segment of each pattern and a ridge direction thereof. It may be understood that, for two identical patterns in the design layout, the first segments of the two patterns exhibit a one-to-one correspondence. For example, taking two completely identical quadrilaterals in the design layout as an example, since a relative positional relationship between a first segment of a first quadrilateral and a corresponding first ridge point is completely consistent with a relative positional relationship between a first segment of a second quadrilateral and a corresponding second ridge point, in the process of generating the mask patterns, the mask patterns corresponding to the first segments of the two quadrilaterals may be kept consistent. Similarly, it may be seen that, the mask patterns corresponding to the remaining first segments of the two quadrilaterals may also be kept consistent, such that two identical local mask patterns may be generated based on two identical quadrilaterals.

In the first design layout, for the plurality of local design layouts which are at different positions but have an identical pattern, since the relative positional relationship between each first segment in the plurality of local design layouts and its corresponding ridge point is the same, the correspondingly generated plurality of local mask patterns may also be kept consistent, thereby ensuring data consistency in the process of generating the mask patterns based on the design layouts.

In the aforesaid embodiments, since the main graphic in the first design layout has accurate coordinate information, after an appropriate rendering resolution is selected, the first design layout may be rendered as data at an appropriate resolution to be input to a corresponding optimization model for prediction.

In some embodiments, the aforesaid S130 may include sub-steps of:

S910, calculating a difference between the model prediction result and the first design layout to obtain a prediction ridge point pattern corresponding to the first design layout; and

S920, performing data processing on the prediction ridge point pattern to obtain a plurality of ridge points and corresponding ridge directions and determine a ridge point pattern.

In this embodiment, after the difference between the model prediction result predicted by the target optimization model and the first design layout is calculated, the prediction ridge point pattern predicted by the model may be obtained. Data processing is performed on the prediction ridge point pattern, and the plurality of ridge points predicted by the model may be obtained.

In S910, after the model prediction result output by the target optimization model is obtained, a difference between the model prediction result and the rendered main graphic of the first design layout is calculated to obtain the prediction ridge point pattern corresponding to the first design layout.

In S920, based on the prediction ridge point pattern, the position coordinates of a plurality of ridge points and the ridge direction of each ridge point may be obtained by data processing. For example, based on the prediction ridge point pattern, the position coordinates and the ridge directions of the ridge points may be extracted by a post-processing algorithm. Based on the position coordinates and the ridge directions of the ridge points, a ridge point pattern for ILT may be generated.

In S140, after the ridge points corresponding to the first design layout are extracted, the first mask pattern may be generated by ILT technology based on the first design layout and the ridge points.

It may be understood that, in the aforesaid embodiments, in the model training process, each main graphic serving as a sample in the training set has the same ridge points for the identical local design layouts. Therefore, when the first design layout is predicted using the trained optimization model, for the identical local designs in the first design layout, the obtained model prediction result may also provide the same ridge points, such that the local mask patterns obtained after optimization of the identical local design layouts may also be kept consistent.

Based on the same inventive concept, the present application further provides a mask pattern optimization device, which will be illustrated in detail below with reference to FIG. 11.

FIG. 11 shows a schematic structural view of a mask pattern optimization device 1100 according to an embodiment of the present application.

As shown in FIG. 11, the mask pattern optimization device 1100 may include: a determination module 1101, configured to determine a target optimization model from a plurality of optimization models based on an optimization accuracy requirement, where the optimization models are obtained by training a design layout and a ridge point pattern with consistency; a model prediction module 1102, configured to input a first design layout to the target optimization model to obtain a model prediction result; a ridge point extraction module 1103, configured to determine a ridge point pattern based on the model prediction result and the first design layout, where the ridge point pattern includes a plurality of ridge points containing direction information; and a pattern optimization module 1104, configured to generate a first mask pattern based on the first design layout and the ridge points.

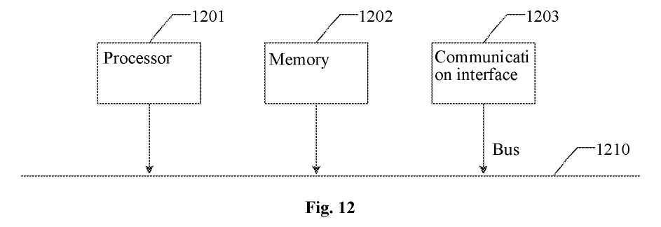

FIG. 12 shows a schematic structural view of the electronic device according to an embodiment of the present application. The electronic device may be at least one of a computer, a server, or a document generation dedicated device. The electronic device includes a processor 1201 and a memory 1202 storing computer program instructions.

Specifically, the processor 1201 may include a central processing unit (CPU), or an Application Specific Integrated Circuit (ASIC), or may be configured as one or more integrated circuits for implementing the embodiments of the present application.

The memory 1202 may include a mass memory for data or instructions. By way of example but not limitation, the memory 1202 may include a Hard Disk Drive (HDD), a floppy disk drive, a flash memory, an optical disk, a magneto-optical disk, a magnetic tape, or an Universal Serial Bus (USB) drive, or a combination of two or more thereof. Where appropriate, the memory 1202 may include a removable or non-removable (or fixed) medium. Where appropriate, the memory 1202 may be internal or external to the electronic device. In a particular embodiment, the memory 1202 is a non-volatile solid state memory.

The memory 1202 may include a read only memory (ROM), a flash memory device, a random access memory (RAM), a magnetic disk storage medium device, a optical storage medium device, an electrical, optical, or other physical/tangible memory storage device. Accordingly, the memory 1202 generally includes one or more tangible (non-transitory) computer-readable storage media (such as, memory device) of software that may be encoded with computer-executable instructions and, the software, when executed (for example by one or more processors), is operable to perform the operations described in the methods according to the above aspects of the present application.

The processor 1201 implements any one of the mask pattern optimization methods in the above embodiments by reading and executing the computer program instructions stored in the memory 1202.

In an example, the electronic device may further include a communication interface 1203 and a bus 1210. As shown in FIG. 12, the processor 1201, the memory 1202, and the communication interface 1203 are connected to each other by the bus 1210 and communicate with each other.

The communication interface 1203 is mainly used for achieving communication between various modules, apparatus, units, and/or devices in the embodiments of the present application.

The bus 1210 includes hardware, software or both thereof for coupling components of the electronic device to each other. By way of example but not limitation, the bus may include an accelerated graphics port (AGP) or other graphics bus, an enhanced industry standard architecture (EISA) bus, a front side bus (FSB), a hyper transport (HT) interconnect, an industry standard architecture (ISA) bus, an infinite bandwidth interconnect, a low pin count (LPC) bus, a memory bus, a micro channel architecture (MCA) bus, a peripheral component interconnect (PCI) bus, a PCI-Express (PCI-X) bus, a serial advanced technology attachment (SATA) bus, a video electronics standards association local (VLB) bus, or other suitable bus, or the combination of two or more thereof. Where appropriate, the bus 1210 may include one or more buses. Although the embodiments of the present application describe and illustrate particular buses, any suitable bus or interconnect is contemplated by the present application.

Based on the mask pattern optimization method, the electronic device may implement the mask pattern optimization method and the mask pattern optimization device described with reference to FIGS. 1 to 11.

In addition, the embodiments of the present application may provide a computer storage medium for implementing the mask pattern optimization method in the above embodiments. The computer storage medium has stored thereon computer program instructions which, when executed by a processor, implement any one of the mask pattern optimization methods in the above embodiments.

Furthermore, the embodiments of the present application further provide a computer program product including a computer program which, when executed by a processor, implements the steps and the corresponding contents of the foregoing method embodiments.

The term “and/or” used herein refers to only an association relationship for describing associated objects, which includes three possible kinds of relationships. For example, “A and/or B” may represent three possible cases including “A existing alone”, “A and B existing simultaneously”, and “B existing alone”. Further, in this document, the character “/” generally indicates an “or” relationship between the associated terms before and after it.

It should be understood that, in the embodiments of the present application, “B corresponding to A” means that B is associated with A, and B may be determined from A. However, it should also be understood that, determining B from A not only means that B is determined from A alone, but also means that B is determined from A and/or other information.

The above are only specific embodiments of the present application. The protection scope of the present application is not limited to this, and any person skilled in the art can easily think of various equivalent modifications or replacements within the technical scope disclosed in the present application, and these modifications or replacements shall all be within the protection scope of the present application. Therefore, the protection scope of the present application shall be defined by the claims.

What is claimed is:

1. A mask pattern optimization method, comprising:
determining a target optimization model from a plurality of optimization models based on an optimization accuracy requirement, wherein the plurality of optimization models are obtained by training with a design layout and a ridge point pattern with consistency;
inputting a first design layout to the target optimization model to obtain a model prediction result;
determining a ridge point pattern based on the model prediction result and the first design layout, wherein the ridge point pattern comprises a plurality of ridge points containing direction information; and
generating a first mask pattern based on the first design layout and the ridge points.

2. The mask pattern optimization method according to claim 1, wherein before the determining a target optimization model from a plurality of optimization models based on an optimization accuracy requirement, the method further comprises:
simulating, for each of a plurality of design layouts, a main graphic of the design layout in combination with placed evaluation points to obtain an assist image formed based on the evaluation points in a case where an exposure graphic contour obtained by simulation satisfies a verification condition;
determining a plurality of ridge points and corresponding ridge directions from the assist image;
determining a first segment of the main graphic corresponding to each of the ridge points to obtain a correspondence relationship between the ridge point and the first segment, wherein the first segment is a portion of an edge of the main graphic;
performing traversal calculation on each of the first segments in the main graphic, and grouping first segments with a same traversal result into a same group;
adjusting the ridge point corresponding to each of the first segments in each group such that a relative positional relationship between each of the first segments in the same group and the corresponding ridge point is consistent; and
training, at different rendering resolutions, preset models by taking rendered main graphics as input parameters and rendered mixed patterns as output parameters to obtain optimization models at different resolutions, wherein the mixed patterns are formed by superimposing the rendered main graphics and rendered ridge point patterns which comprise a plurality of ridge points containing direction information.

3. The mask pattern optimization method according to claim 2, wherein the simulating, for each of a plurality of design layouts, a main graphic of the design layout in combination with placed evaluation points to obtain an assist image formed based on the evaluation points in a case where an exposure graphic contour obtained by simulation satisfies a verification condition comprises:
placing sub-resolution assist feature points around the main graphic of the design layout;
inputting the main graphic and the sub-resolution assist feature points to a simulation model to obtain the exposure graphic contour;
adjusting, in a case where the exposure graphic contour does not match a verification pattern contour, the sub-resolution assist feature points and re-inputting them to the simulation model until the exposure graphic contour matches the verification pattern contour; and
generating a sub-resolution assist image based on the sub-resolution assist feature points satisfying a verification condition.

4. The mask pattern optimization method according to claim 3, wherein the determining a plurality of ridge points and corresponding ridge directions from the assist image comprises:
pixelating the sub-resolution assist image to obtain an original pixel matrix;
performing gradient processing on the original pixel matrix to obtain a first-order gradient value image;
determining a local peak point as the ridge point from the first-order gradient value image; and
selecting, based on a second-order gradient of the original pixel matrix, a direction with a largest second-order gradient value around each of the ridge points as the ridge direction.

5. The mask pattern optimization method according to claim 4, wherein the determining a first segment of the main graphic corresponding to each of the ridge points to obtain a correspondence relationship between the ridge point and the first segment comprises:
setting a plurality of breakpoints on each edge of the main graphic;
dividing each edge of the main graphic into a plurality of first segments based on the plurality of breakpoints;
determining, for each of the ridge points, one of the first segments with a closest distance to the ridge point in the main graphic; and
constructing the correspondence relationship between the ridge point and the first segment with the closest distance.

6. The mask pattern optimization method according to claim 5, wherein the performing traversal calculation on each of the first segments in the main graphic, and grouping the first segments with a same traversal result into a same group comprises:
traversing each of the first segments in the main graphic to obtain adjacent first segments within a preset range of each of the first segments;
calculating a sum of mapping values of adjacent first segments of each of the first segments as an eigenvalue of each of the first segments; and
grouping the first segments with a same eigenvalue into a same group.

7. The mask pattern optimization method according to claim 6, wherein the adjusting the ridge point corresponding to each of the first segments in each group comprises:
selecting, for each group, one from the first segments in the group as a sample segment; and
moving the ridge point corresponding to the sample segment, according to a movement trajectory from the sample segment to another first segment, to a corresponding position of the another first segment, and updating a correspondence relationship between the another first segment and the ridge point.

8. The mask pattern optimization method according to claim 7, wherein the selecting, for each group, one from the first segments in the group as a sample segment comprises:
acquiring position information of a center point of the sub-resolution assist image;
calculating, for each group, a distance of each of the first segments in the group from the center point; and
selecting one of the first segments that has a shortest distance from the center point as the sample segment.

9. The mask pattern optimization method according to claim 7, wherein the training, at different rendering resolutions, preset models by taking rendered main graphics as input parameters and rendered mixed patterns as output parameters to obtain optimization models at different resolutions comprises:
constructing preset models at different rendering resolutions; and
generating, for each of the rendering resolutions, a training set at the corresponding rendering resolution, and training the preset model with the training set to obtain a corresponding optimization model, wherein input parameters of the training set are rendered main graphics of the plurality of design layouts, and output parameters of the training set are mixed patterns formed by superimposing the rendered main graphics of the plurality of design layouts and rendered ridge point patterns.

10. The mask pattern optimization method according to claim 1, wherein the determining a ridge point pattern based on the model prediction result and the first design layout comprises:
calculating a difference between the model prediction result and the first design layout to obtain a prediction ridge point pattern corresponding to the first design layout; and
performing data processing on the prediction ridge point pattern to obtain a plurality of ridge points and corresponding ridge directions and determine the ridge point pattern.

11. An electronic device, comprising a processor and a memory storing computer program instructions, wherein the processor, when executes the computer program instructions, carries out steps of the mask pattern optimization method according to claim 1.

12. A computer program product, wherein instructions in the computer program product, when executed by a processor, carry out steps of the mask pattern optimization method according to claim 1.
